(19) United States
(12) Patent Application Publication
(10) Pub. No.: US 2014/0240705 A1
(43) Pub. Date: Aug. 28, 2014

(54) SEMICONDUCTOR DEVICE, RETICLE METHOD FOR CHECKING POSITION MISALIGNMENT AND METHOD FOR MANUFACTURING POSITION MISALIGNMENT CHECKING MARK

(71) Applicant: Kabushiki Kaisha Toshiba, Tokyo (JP)

(72) Inventor: Michiya TAKIMOTO, Mie (JP)

(73) Assignee: Kabushiki Kaisha Toshiba, Tokyo (JP)

(21) Appl. No.: 13/955,141

(22) Filed: Jul. 31, 2013

Related U.S. Application Data
(60) Provisional application No. 61/769,801, filed on Feb. 27, 2013.

(51) Int. Cl. G03F 9/00

(52) U.S. Cl. CPC G03F 9/00
USPC 356/401

(57) ABSTRACT

According to one embodiment, there is provided a semiconductor device including a circuit area in which an integrated circuit is formed, a position misalignment checking mark of which a contrasting density is detected under polarized illumination and is not detectable under non-polarized illumination, and a peripheral pattern that is disposed on a periphery of the position misalignment checking mark and has a contrasting density that is not detectable under the polarized illumination.

### CROSS-REFERENCE TO RELATED APPLICATIONS

This application is based upon and claims the benefit of priority from Provisional Patent Application No. 61/769801, filed on Feb. 27, 2013; the entire contents of which are incorporated herein by reference.

### FIELD

Embodiments described herein relate generally to a semiconductor device, a reticle, a method for checking a position misalignment, and a method for manufacturing a position misalignment checking mark.

### BACKGROUND

In the semiconductor manufacturing process, in order to position an upper layer pattern formed in an upper layer and a lower layer pattern formed in a lower layer or to measure a position misalignment, position misalignment checking marks are used.

### BRIEF DESCRIPTION OF THE DRAWINGS

FIG. 1A is a plan view that illustrates a schematic configuration of a position misalignment checking mark according to a first embodiment, and FIG. 1B is a cross-sectional view that illustrates a schematic configuration of a semiconductor device in which the position misalignment checking mark illustrated in FIG. 1A is formed.

FIG. 2A is a perspective view that illustrates a method for exposing the position misalignment checking mark according to the first embodiment, FIG. 2B is a perspective view that illustrates a schematic configuration of a lower layer of a semiconductor device in which the position misalignment checking mark illustrated in FIG. 2A is formed, FIG. 2C is a schematic configuration of an upper layer of the semiconductor device in which the position misalignment checking mark illustrated in FIG. 2A is formed, and FIG. 2D is a perspective view that illustrates a method for measuring the position misalignment checking marks illustrated in FIGS. 2B and 2C.

FIG. 3A is a plan view that illustrates an example of detection of the position misalignment checking mark illustrated in FIG. 1A, which is observed under polarized illumination, and FIG. 3B is a plan view that illustrates an example of detection of the position misalignment checking mark illustrated in FIG. 1A, which is observed under non-polarized illumination.

FIG. 4A is a plan view that illustrates a schematic configuration of a position misalignment checking mark according to a comparative example, and FIG. 4B is a cross-sectional view that illustrates a schematic configuration of a semiconductor device in which the position misalignment checking mark illustrated in FIG. 4A is formed.

FIGS. 5A to 5E are cross-sectional views that illustrate a method for manufacturing a position misalignment checking mark according to a second embodiment.

### DETAILED DESCRIPTION

According to an embodiment, a circuit area, a position misalignment checking mark, and a peripheral pattern are disposed. In the circuit area, an integrated circuit is formed. The contesting density of the position misalignment checking mark is detected under polarized illumination and is not detectable under non-polarized illumination. The peripheral pattern is arranged on a periphery of the position misalignment checking mark, and the contrasting density thereof is not detectable under the polarized illumination.

Hereinafter, a semiconductor device, a reticle, a method for checking a position misalignment, and a method for manufacturing a position misalignment checking mark according to embodiments will be described in detail with reference to the accompanying drawings. However, the present invention is not limited to the embodiments.

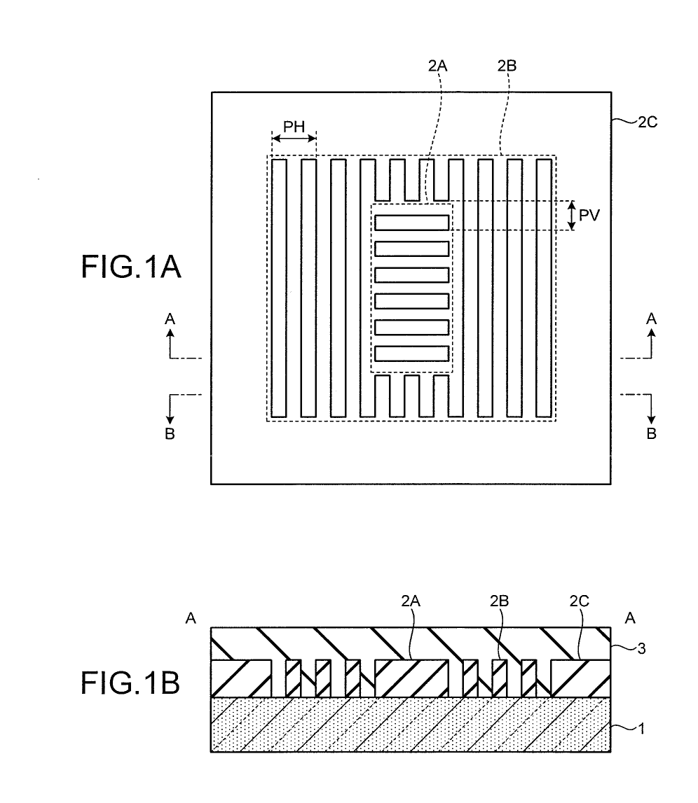

FIG. 1A is a plan view that illustrates a schematic configuration of a position misalignment checking mark according to a first embodiment, and FIG. 1B is a cross-sectional view that illustrates a schematic configuration of a semiconductor device in which the position misalignment checking mark illustrated in FIG. 1A is formed. FIG. 1B is a view taken along line A-A illustrated in FIG. 1A.

In FIGS. 1A and 1B, a position misalignment checking mark 2A is formed on an underlayer 1, and, a peripheral pattern 2B is formed on the periphery of the position misalignment checking mark 2A. On the periphery of the peripheral pattern 2B, a beta pattern 2C is formed. Here, the underlayer 1 may be a semiconductor substrate, an insulating layer formed on a semiconductor substrate, or a conductive layer formed on an insulating layer, and is not particularly limited. In addition, the position misalignment checking mark 2A may be used as an alignment mark or may be used as a misalignment measurement mark.

The contrasting density of the position misalignment checking mark 2A is detected under polarized illumination and is not detectable under non-polarized illumination. The contrasting density of the peripheral pattern 2B is not detectable under polarized illumination. In the position misalignment checking mark 2A, a first line and space is disposed, and a second line and space is disposed in the peripheral pattern 2B. The first line and space may be perpendicular to the second line and space. The pattern density of the first line and space and the pattern density of the second line and space may be the same. The pattern pitch PV of the first line and space and the pattern pitch PH of the second line and space may be the same. The pattern pitch PV of the first line and space and the pattern pitch PH of the second line and space may be the same as the resolution limit of the non-polarized illumination.

A thin film 3 is formed on the position misalignment checking mark 2A and the peripheral pattern 2B. The thin film 3 may be flattened using a method such as CMP. In addition, the thin film 3, for example, may be an interlayer insulating film such as a silicon oxide film.

Here, by disposing the first line and space in the position misalignment checking mark 2A and disposing the second line and space in the peripheral pattern 2B, the pattern densities of the position misalignment checking mark 2A and the peripheral pattern 2B can be configured to be the same. Accordingly, the thin film 3 can be flattened using a method such as CMP while dishing of the thin film 3 is suppressed, and accordingly, pattern formation can be performed while responding to a decrease in the focus margin at the time of exposure.

In addition, by disposing the first line and space to be perpendicular to the second line and space, the position misalignment checking mark 2A can be detected while the peripheral pattern 2B is not detected under polarized illumination, whereby the position misalignment can be checked.

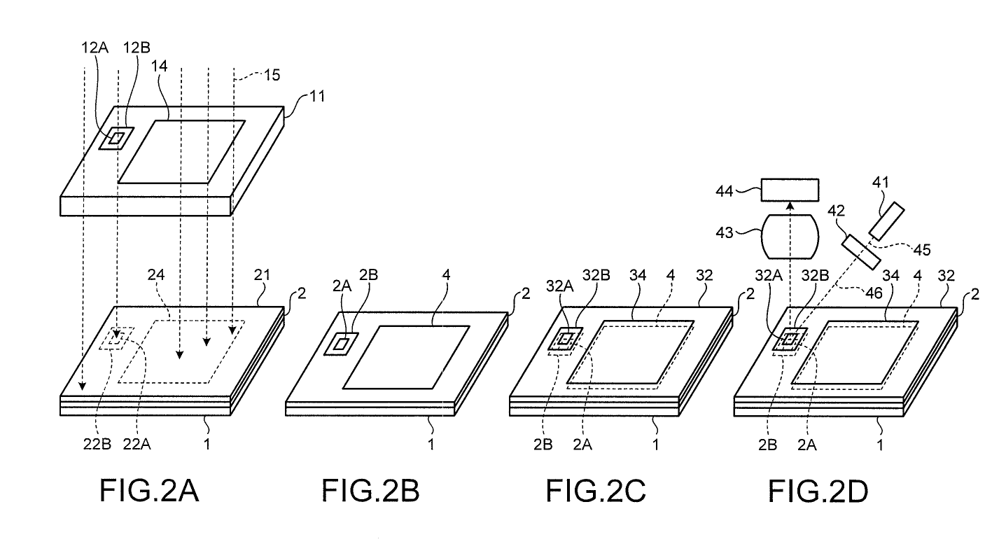

FIG. 2A is a perspective view that illustrates a method for exposing the position misalignment checking mark according to the first embodiment, FIG. 2B is a perspective view that illustrates a schematic configuration of a lower layer of a semiconductor device in which the position misalignment checking mark illustrated in FIG. 2A is formed, FIG. 2C is a schematic configuration of an upper layer of the semiconductor device in which the position misalignment checking mark illustrated in FIG. 2A is formed, and FIG. 2D is a perspective view that illustrates a method for measuring the position misalignment checking marks illustrated in FIGS. 2B and 2C.

In FIG. 2A, a circuit area 14 in which a circuit pattern is formed is disposed in a reticle 11. In addition, in the reticle 11, a position misalignment checking mark 12A is formed, and a peripheral pattern 12B is arranged on the periphery of the position misalignment checking mark 12A.

On an underlayer 1, a lower layer 2 is disposed, and a resist layer 21 is formed on the lower layer 2. By emitting exposure light 15 to the resist layer 21 through the reticle 11, a latent image pattern 24 corresponding to the circuit pattern of the circuit area 14 is formed. Simultaneously with the formation the latent image pattern 24, a latent image mark 22A corresponding to the position misalignment checking mark 12A is formed on the resist layer 21, and a latent image pattern 22B corresponding to the peripheral pattern 12B is formed in the resist layer 21.

Then, by developing the resist layer 21 in which the latent image mark 22A and the latent image patterns 22B and 24 are formed, a resist pattern corresponding to the latent image mark 22A and the latent image patterns 22B and 24 are formed on the lower layer 2. Then, by etching the lower layer 2 with the resist pattern being used as a mask, as illustrated in FIG. 2B, the circuit pattern of the circuit area 14 is transferred to a circuit area 4 of the lower layer 2, and the position misalignment checking mark 2A and the peripheral pattern 2B to which the position misalignment checking mark 12A and the peripheral pattern 12B have been transferred are formed in the lower layer 2.

Next, as illustrated in FIG. 2C, an upper layer 32 is formed on the lower layer 2. In the upper layer 32, a circuit area 34, a position misalignment checking mark 32A, and a peripheral pattern 32B are disposed. It may be configured such that the circuit area 34 is arranged so as to overlap the circuit area 4, the position misalignment checking mark 32A is arranged so as to overlap the position misalignment checking mark 2A, and the peripheral pattern 32B is arranged so as to overlap the peripheral pattern 2B.

Next, as illustrated in FIG. 2D, by passing non-polarized illumination 45 emitted from a light source 41 through a polarizing device 42, polarized illumination 46 is generated. Then, by emitting the polarized illumination 46 to the position misalignment checking marks 2A and 32A, the contrasting densities of the position misalignment checking marks 2A and 32A are generated, and the position misalignment checking marks 2A and 32A are detected by an imaging device 44 through an optical system 43. Then, based on the position misalignment checking marks 2A and 32A detected by the imaging device 44, a position misalignment between the lower layer 2 and the upper layer 32 can be checked.

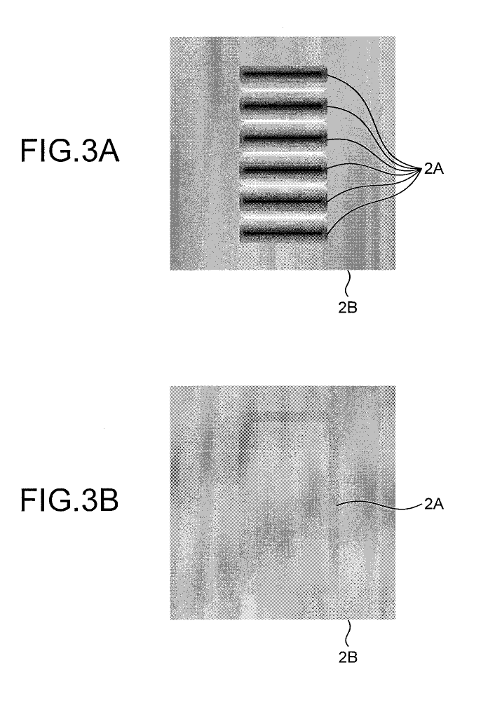

FIG. 3A is a plan view that illustrates an example of detection of the position misalignment checking mark illustrated in FIG. 1A, which is observed under polarized illumination, and FIG. 3B is a plan view that illustrates an example of detection of the position misalignment checking mark illustrated in FIG. 1A, which is observed under non-polarized illumination.

In FIG. 3A, under polarized illumination, a contrasting density is generated in the position misalignment checking mark 2A, and a contrasting density is not generated in the peripheral pattern 2B. On the other hand, as illustrated in FIG. 3B, under non-polarized illumination, a contrasting density is not generated in the position misalignment checking mark 2A and the peripheral pattern 2B. Accordingly, under the polarized illumination, the position misalignment checking mark 2A can be detected, and, as illustrated in FIG. 2D, a position misalignment between the lower layer 2 and the upper layer 32 can be checked.

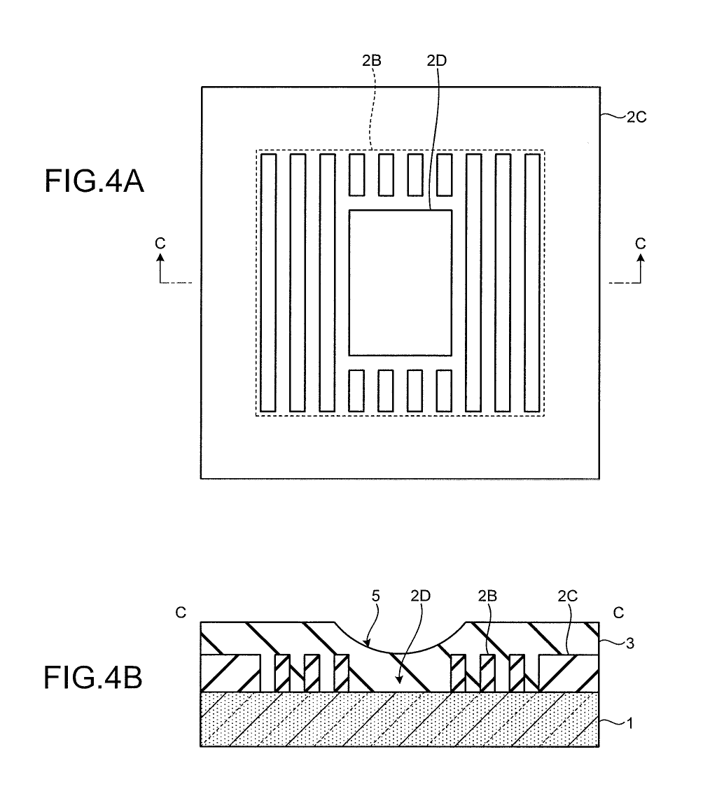

FIG. 4A is a plan view that illustrates a schematic configuration of a position misalignment checking mark according to a comparative example, and FIG. 4B is a cross-sectional view that illustrates a schematic configuration of a semiconductor device in which the position misalignment checking mark illustrated in FIG. 4A is formed. FIG. 4B is a view taken along line C-C illustrated in FIG. 4A.

In FIG. 4A, in this comparative example, instead of the position misalignment checking mark 2A illustrated in FIG. 1A, a position misalignment checking mark 2D is disposed. The position misalignment checking mark 2D is formed in an opening pattern. Accordingly, the pattern density of the position misalignment checking mark 2D is lower than that of the peripheral pattern 2B. As a result, when the thin film 3 is flattened using a method such as CMP, it is easier to plane the thin film 3 disposed on the position misalignment checking mark 2D than the thin film 3 disposed on the peripheral pattern 2B, whereby dishing 5 is generated in the thin film 3.

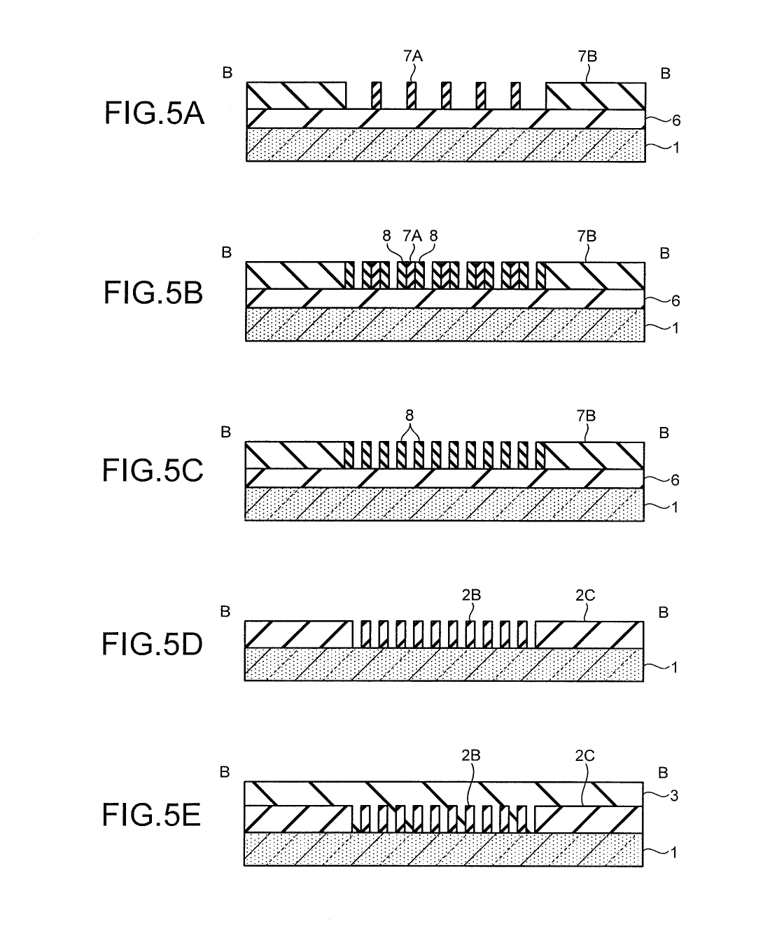

FIGS. 5A to 5E are cross-sectional views that illustrate a method for manufacturing a position misalignment checking mark according to a second embodiment. In this embodiment, a method is illustrated in which a line and space of a portion cut along line B-B illustrated in FIG. 1A is formed in a side-wall processing process.

In FIG. 5A, a processing target film 6 is formed on the underlayer 1. Here, the processing target film 6 may be a semiconductor, an insulating body, or a conductive body. Then, core patterns 7A and 7B are formed on the processing target film 6. Here, the core pattern 7A may be a line and space, and the core pattern 7B may be a beta pattern. As the material of the core patterns 7A and 7B, a resist material may be used, or a hard mask material such as a BSG film or a silicon nitride film may be used. In addition, the core patterns 7A and 7B may be slimmed by using a method such as isotropic etching so as to slim the line width of the core patterns 7A and 7B.

Next, as illustrated in FIG. 5B, for example, by using a method such as CVD, a side wall material having a high selection rate for the core patterns 7A and 7B is deposited on the whole face on the processing target film 6 that includes the side walls of the core patterns 7A and 7B. As the side wall material having a high selection rate for the core patterns 7A and 7B, for example, in a case where the core patterns 7A and 7B are formed from a BSG film, a silicon nitride film may be used. Then, by performing anisotropic etching of the side wall material, the processing target film 6 is exposed with the side wall material remaining on the side wall of the core patterns 7A and 7B. At this time, in the side wall of the core patterns 7A and 7B, a side wall pattern 8 is formed.

Next, as illustrated in FIG. 5C, after the core pattern 7B is covered with a resist material or the like, by using a method such as wet etching, the core pattern 7A is removed from the upper side of the processing target film 6 with the side wall pattern 8 and the core pattern 7B remaining on the processing target film 6.

Next, as illustrated in FIG. 5D, by processing the processing target film 6 with the side wall pattern 8 and the core pattern 7B being used as a mask, the peripheral pattern 2B to which the side wall pattern 8 has been transferred is formed on the underlayer 1, and the beta pattern 2C to which the core pattern 7B has been transferred is formed on the underlayer 1.

Next, as illustrated in FIG. 5E, the thin film 3 is formed on the underlayer 1 so as to cover the peripheral pattern 2B and the beta pattern 2C by using a method such as CVD. Then, by causing the thin film 3 to be thin by using a method such as CMP, the thin film 3 is flattened to be thin. Here, by disposing a line and space in the position misalignment checking mark 2A and the peripheral pattern 2B, the pattern densities of the position misalignment checking mark 2A and the peripheral pattern 2B can be configured to be the same, whereby the dishing of the thin film 3 can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a circuit area in which an integrated circuit is formed;
a position misalignment checking mark of which a contrasting density is detected under polarized illumination and is not detectable under non-polarized illumination; and
a peripheral pattern that is disposed on a periphery of the position misalignment checking mark and has a contrasting density that is not detectable under the polarized illumination.

2. The semiconductor device of claim 1, further comprising:
a first line and space that is disposed in the position misalignment checking mark; and
a second line and space that is disposed in the peripheral pattern and is perpendicular to the first line and space.

3. The semiconductor device of claim 2, wherein pattern densities of the first line and space and the second line and space are the same.

4. The semiconductor device of claim 3, wherein pattern pitches of the first line and space and the second line and space are the same.

5. The semiconductor device of claim 4, wherein the pattern pitch is the same as a resolution limit of the non-polarized illumination.

6. A reticle comprising:
a circuit area in which a circuit pattern is formed;
a position misalignment checking mark of which a contrasting density is detected under polarized illumination and is not detectable under non-polarized illumination; and
a peripheral pattern that is disposed on a periphery of the position misalignment checking mark and has a contrasting density that is not detectable under the polarized illumination.

7. The reticle of claim 6, further comprising:
a first line and space that is disposed in the position misalignment checking mark; and
a second line and space that is disposed in the peripheral pattern and is perpendicular to the first line and space.

8. The reticle of claim 7, wherein pattern densities of the first line and space and the second line and space are the same.

9. The reticle of claim 8, wherein pattern pitches of the first line and space and the second line and space are the same.

10. The reticle of claim 9, wherein the pattern pitch is the same as a resolution limit of the non-polarized illumination.

11. A method for checking a position misalignment, the method comprising:
forming a position misalignment checking mark of which a contrasting density is detected under polarized illumination and is not detectable under non-polarized illumination and a peripheral pattern that is disposed on a periphery of the position misalignment checking mark and has a contrasting density that is not detectable under the polarized illumination in a target layer; and
observing the position misalignment checking mark under the polarized illumination.

12. The method of claim 11,
wherein a first line and space that is disposed in the position misalignment checking mark, and
a second line and space that is disposed in the peripheral pattern and is perpendicular to the first line and space are included.

13. The method of claim 12, wherein pattern densities of the first line and space and the second line and space are the same.

14. The method of claim 13, wherein pattern pitches of the first line and space and the second line and space are the same.

15. The method of claim 14, wherein the pattern pitch is the same as a resolution limit of the non-polarized illumination.

16. A method for manufacturing a position misalignment checking mark, the method comprising:
forming a position misalignment checking mark of which a contrasting density is detected under polarized illumination and is not detectable under non-polarized illumination and a peripheral pattern that is disposed on a periphery of the position misalignment checking mark and has a contrasting density that is not detectable under the polarized illumination in a target layer;
forming a thin film in the position misalignment checking mark and the peripheral pattern; and
flattening the thin film by CMP.

17. The method of claim 16,
wherein a first line and space that is disposed in the position misalignment checking mark and a second line and space that is disposed in the peripheral pattern and is perpendicular to the first line and space are included, and
the first line and space and the second line and space are formed by a side wall processing process.

18. The method of claim 17, wherein pattern densities of the first line and space and the second line and space are the same.

19. The method of claim 18, wherein pattern pitches of the first line and space and the second line and space are the same.

20. The method of claim 19, wherein the pattern pitch is the same as a resolution limit of the non-polarized illumination.
